(19) United States
(12) Patent Application Publication
(10) Pub. No.: US 2004/0089926 A1
(43) Pub. Date: May 13, 2004

(54) Ultra thin semiconductor device

(75) Inventors: Cheng-Ho Hsu, Kaohsiung (TW); Yi-Hua Chang, Feng-Shan City (TW); Kuei-Hua Liu, Kaohsiung (TW)

Correspondence Address: Cooper & Dunham LLP, 1185 Avenue of the Americas, New York, NY, 10036, US

(73) Assignee: Taiwan IC Packaging Corporation

(21) Appl. No.: 10/292,055

(22) Filed: Nov. 12, 2002

(51) Int. Cl. H01L 23/02

(52) U.S. Cl. 257/678

(57) ABSTRACT

An ultra thin semiconductor device has a lead frame for holding a chip and an encapsulant sealing the chip and the lead frame. The lead frame has a die pad and multiple leads for wire bonding with the chip. A die recess to hold the chip is defined in the die pad. A depth of the die recess decreases a total height of the chip and the die pad to provide the wires enough bonding space. That is, the semiconductor device easily has a 0.4 mm thickness to be an ultra thin semiconductor product.

### BACKGROUND OF THE INVENTION

1. Field of the Invention

The present invention relates to an ultra thin semiconductor device, and more particularly to a semiconductor device in an ultra thin package.

2. Description of Related Art

To decrease the total height of a semiconductor device, some semiconductor devices are used a single-side potting glue process to package the semiconductor device. With reference to FIG. 6, one conventional single-side package of a semiconductor device includes a chip (40), a lead frame (41), wires (44) and encapsulant (42). The lead frame (41) has a top, a bottom, a die pad (411) and multiple leads (412) around the die pad (411). The wires (44) are attached to the chip (40) and the leads (412) of the lead frame (41). The die pad (411) and the leads (412) are the same thickness.

To prevent the encapsulant (42) from flowing onto the bottom of the lead frame (41), a polyimide tape (not shown) is attached to the bottom of the lead frame (41) before the single-side potting glue process (i.e. applying encapsulant (42) to one side of the device) is carried out. After attaching the chip (40) to the die pad (411) and attaching the wires (44), the single-side potting glue process is carried out. Then the tape is removed from the bottom of the lead frame (41) and the encapsulant (42) to form the single-side package of the semiconductor device. Based on the forgoing the description, the single-sided package of the semiconductor device is thinner than a dual-sided package of a semiconductor device. Because of the thickness of the individual element and the necessary tolerances, a 0.4 mm thickness is very hard to achieve with the conventional single-sided package of the semiconductor device. The chip's is about 0.1 mm to 0.15 mm thick which adds 0.10 mm to 0.15 mm to the thickness of the die pad for an overall thickness of the semiconductor device of at least 0.20 mm to 0.30 mm. Furthermore, connecting the wires to the chip requires additional space above the top surface of the chip. The encapsulant must be higher than the wires to ensure that all elements are effectively encapsulated, which further adds to the total height of the semiconductor device. Therefore, achieving a 0.4 mm semiconductor device is virtually impossible.

To overcome the shortcomings, the present invention provides an improved semiconductor device to mitigate or obviate the aforementioned problems.

### SUMMARY OF THE INVENTION

The main objective of the invention is to provide an ultra thin semiconductor device that is easily packaged to be an ultra thin product.

Other objectives, advantages and novel features of the invention will become more apparent from the following detailed description when taken in conjunction with the accompanying drawings.

### BRIEF DESCRIPTION OF THE DRAWINGS

FIG. 1 is a cross sectional side plan view of a semiconductor device in accordance with the present invention;

FIG. 2 is a cross sectional side plan view of a second embodiment of a semiconductor device in accordance with the present invention;

FIG. 3 is a cross sectional side plan view of a third embodiment of a semiconductor device in accordance with the present invention;

FIG. 4 is a top view of multiple semiconductor devices in accordance with the present invention;

FIG. 5 is a bottom view of multiple semiconductor devices in FIG. 4; and

FIG. 6 is a cross sectional side plan view of a conventional single-sided semiconductor device made with a potting glue process.

### DETAILED DESCRIPTION OF THE PREFERRED EMBODIMENT

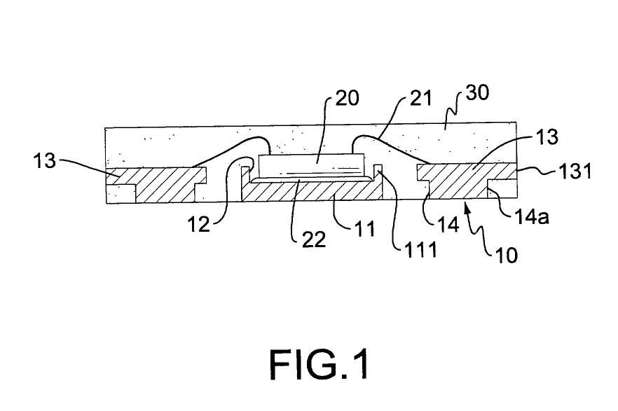

With reference to FIG. 1, an ultra thin semiconductor device includes a chip (20), a lead frame (10), encapsulant (30) and wires (21).

The chip (20) has a top face, a thickness, a bottom (not numbered) and multiple bonding pads (not shown) on the top face of the chip (20). The thickness (not numbered) of the chip (20) is about 0.10 mm to 0.15 mm, and the top face has a finite area.

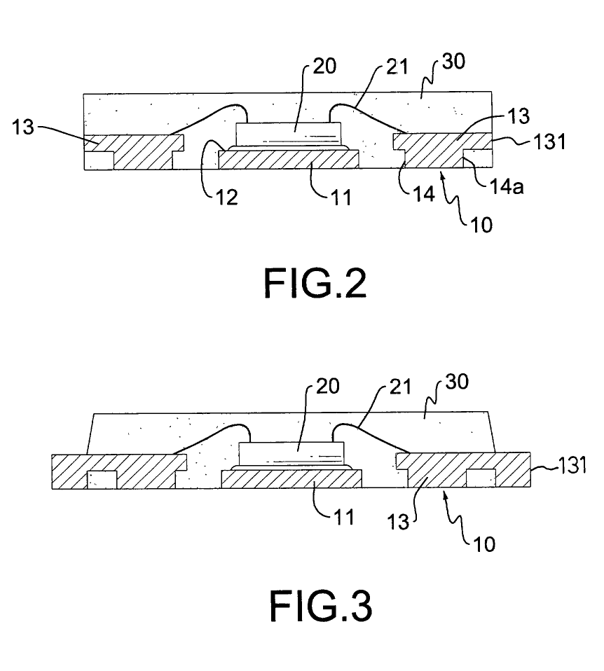

The lead frame (10) includes a die pad (11) and multiple leads (13). The die pad (11) has sides, a top face, a bottom and a die recess (12). The leads (13) have a top face and are arranged near sides of the die pad (11). A die recess (12) with a bottom and a specific area is formed in the die pad (11) in which the bottom of the chip (20) is attached, and sidewalls (111) are formed around the die recess (12). The bottom of the die recess (12) is lower than the top face (not numbered) of each lead (13). The ideal area of the die recess (12) is 120 percent larger than of the area of the top face of the chip (20). With reference to FIG. 2, the die recess (12) may be the same size as the die pad (11) so that the die pad (12) has no the sidewalls (not shown).

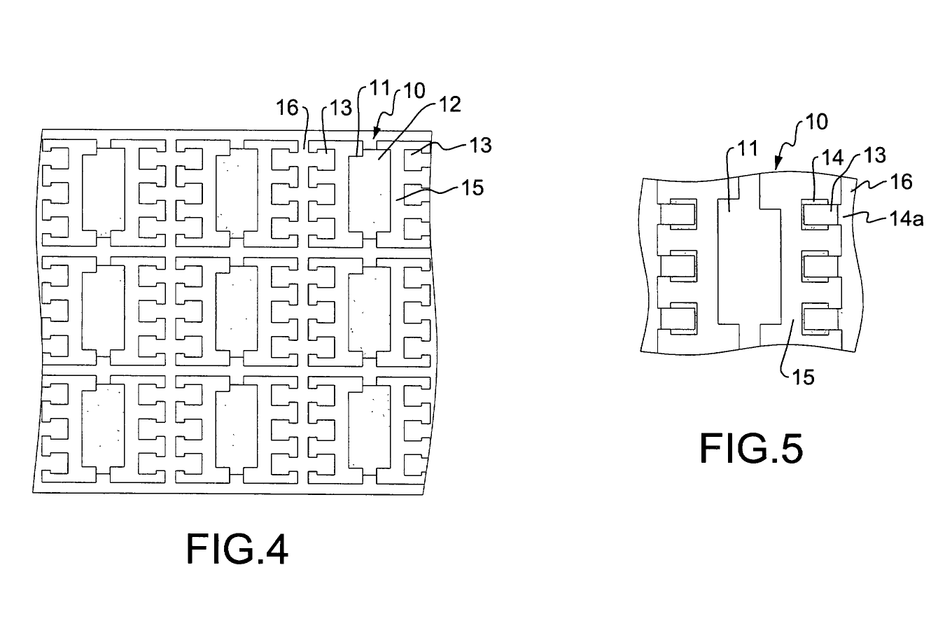

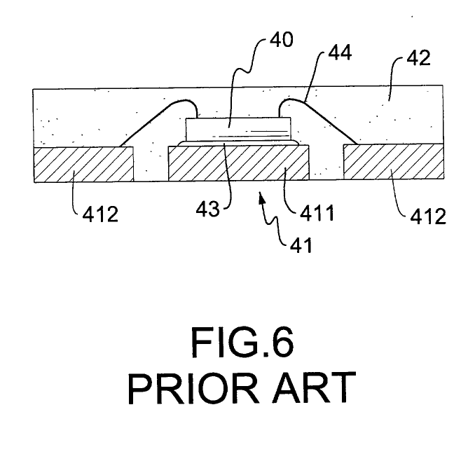

Each lead (13) has a bottom, a top, an inner portion (not numbered) relatively close to the die pad (11) and an outer portion (not numbered) farther away from the die pad (11). A wire (21) is bound to each inner portion and a bonding pad on the chip (20). The outer portion has an exposed end (131). At least one notch (14) is defined on the bottom of the lead (13) to increase the total surface of the lead (13). With reference to FIGS. 2 and 5, two notches (14, 14a) are respectively defined on the bottom of the inner portion and the outer portion. Cutting channels (16) are formed on wafers between the ultra thin semiconductor devices, and the outer portion of the leads (13) extend into the cutting channels (16). With further reference to FIG. 4, the thin outer portion of the lead (13) above the notch (14a) in the cutting channel (16) is easy to cut. The chip (20) is held in the die recess (12), and then the bonding pads on the chip (10) are respectively connected to the corresponding leads (13) of the lead frame (10).

The encapsulant (30) seals the chip (20), lead frame (10) and wires (21). The encapsulant (30) is made of epoxy resin which is applied to the chip (20) and the lead frame (10) by a molding or printing method or the like. With reference to FIG. 2, the exposed end (131) of the lead (13) is flush with the side of the encapsulant (30). With reference to FIG. 3, the exposed end (131) in another embodiment of the lead (13) protrudes beyond the side of the encapsulant (30).

The thickness of the die pad (11) is about 0.10 mm to 0.15 mm, but a depth of the die recess (12) is about 0.05 mm to 0.075 mm. Therefore, when the 0.1 mm to 0.15 mm chip (20) is mounted in the die recess (12), the total height of the chip (20) and the die pad (11) is about 0.15 mm to 0.225 mm. In the wire bonding process, 0.05 mm to 0.075 mm is required to bind the wires (21) to the chip (30) and the lead frame (10). Even allowing for the thickness of the encapsulant, the semiconductor device in accordance with the present invention can be fabricated with a thickness of 0.4 mm, thereby resulting in an ultra thin product.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An ultra thin semiconductor device, comprising
a chip having bonding pads;
a lead frame for holding the chip comprising:
a die pad having sides, a top face and a die recess defined on the top face;
multiple leads around the sides of the die pad, wherein each lead has a bottom, a top surface, an inner portion and an outer portion; and
a wire attached to each respective bonding pad and the inner portion of a corresponding one of the leads; and
an encapsulant having a top surface and sides and sealing the chip attached to the die pad, the lead frame and the wires.

2. The ultra thin semiconductor device as claimed in claim 1, wherein a size of the die recess is equal to a size of the die pad.

3. The ultra thin semiconductor device as claimed in claim 1, wherein a size of the die recess is smaller than a size of the die pad, and the die pad has sidewalls around the die recess.

4. The ultra thin semiconductor device as claimed in claim 1, wherein at least one notch is defined on the bottom of each lead to hold encapsulant.

5. The ultra thin semiconductor device as claimed in claim 1, wherein an end of the outer portion of each lead is exposed at the side of the encapsulant and is flush with the side of the encapsulant.

6. The ultra thin semiconductor device as claimed in claim 1, wherein an end of the outer portion of each lead protrudes from the side the encapsulant.

7. The ultra thin semiconductor device as claimed in claim 4, wherein one notch is defined in the bottom of the inner portion to securely hold the encapsulant and one notch is defined on the bottom of the outer portion, which is adapted to be in a cutting channel to easily cut the cutting channel.

8. The ultra thin semiconductor device as claimed in claim 1, wherein a depth of the die recess is about 0.05 mm to 0.075 mm, and a thickness of the chip is about 0.10 mm to 0.15 mm.
